(19) United States
(12) Patent Application Publication
(10) Pub. No.: US 2016/0113131 A1
(43) Pub. Date: Apr. 21, 2016

(54) VENT ASSEMBLY FOR AN ELECTRONIC DEVICE ENCLOSURE

(71) Applicant: Garmin International, Inc., Olathe, KS (US)

(72) Inventors: Sean R. Ernesti, Gardner, KS (US); Gregory J. Immethun, Lee's Summit, MO (US)

(21) Appl. No.: 14/516,805

(22) Filed: Oct. 17, 2014

(51) Int. Cl. H05K 5/02; B01D 53/22; H05K 5/06

(52) U.S. Cl. CPC H05K 5/0213; H05K 5/069; H05K 5/068; B01D 53/22

(57) ABSTRACT

A housing for an electronic device includes an enclosure for enclosing the electronic device and a vent assembly integrated into the enclosure. The vent assembly includes a recess formed in a wall of the enclosure; a tapped hole formed in a center of the recess and through the wall of the enclosure; a number of vent holes positioned in the recess and formed through the wall of the enclosure; a porous membrane seated within the recess and positioned over the vent holes; a vent cover positioned at least partially over the porous membrane so as to sandwich the porous membrane between the vent holes and the vent cover; and a fastener for fastening the vent cover to the enclosure.

### BACKGROUND

Electronic devices exposed to harsh environments are typically enclosed within weatherproof enclosures. The enclosures typically include vents to equalize pressure and reduce condensation in the enclosures.

### SUMMARY

An embodiment of the present technology includes a housing for an electronic device such as an avionics unit. The housing broadly includes an enclosure for enclosing the electronic device and a vent assembly for venting the enclosure. An embodiment of the vent assembly comprises a recess formed in a wall of the enclosure; a tapped hole formed in the recess and through the enclosure wall; a number of vent holes positioned in the recess and formed through the enclosure wall; a porous membrane seated within the recess and positioned over the vent holes; a vent cover positioned at least partially over the porous membrane so as to retain the porous membrane over the vent holes; and a fastener for fastening the vent cover to the enclosure.

This summary is provided to introduce a selection of concepts in a simplified form that are further described in the detailed description below. This summary is not intended to identify key features or essential features of the claimed subject matter, nor is it intended to be used to limit the scope of the claimed subject matter. Other aspects and advantages of the present invention will be apparent from the following detailed description of the embodiments and the accompanying drawing figures.

### BRIEF DESCRIPTION OF THE DRAWING FIGURES

Embodiments of the present technology are described in detail below with reference to the attached drawing figures, wherein:

FIG. 1 is a perspective view of an exemplary housing constructed in accordance with principles of the present technology.

FIG. 2 is a exploded perspective view of the housing showing parts of the vent assembly removed from its enclosure.

FIG. 3 is a fragmentary plan view of the housing showing the vent assembly and a portion of the enclosure.

FIG. 4 is a fragmentary vertical section view of the housing along line 4-4 of FIG. 3 showing the vent assembly fully attached to the enclosure.

The drawing figures do not limit the present technology to the specific embodiments disclosed and described herein. The drawings are not necessarily to scale, emphasis instead being placed upon clearly illustrating the principles of the technology.

### DETAILED DESCRIPTION

The following detailed description of embodiments of the technology references the accompanying drawings. The embodiments are intended to describe aspects of the technology in sufficient detail to enable those skilled in the art to practice the technology. Other embodiments can be utilized and changes can be made without departing from the scope of the claims. The following detailed description is, therefore, not to be taken in a limiting sense. The scope of the present technology is defined only by the appended claims, along with the full scope of equivalents to which such claims are entitled.

In this description, references to “one embodiment,” “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present technology can include a variety of combinations and/or integrations of the embodiments described herein.

The present technology provides a housing for an electronic device such as an avionics device, marine chartplotter, handheld electronic device, etc. The housing includes a weatherproof enclosure for enclosing the electronic device and a vent assembly for venting the enclosure. Existing weatherproof enclosures have vents that are either too large and complicated or that aren't robust enough for use in enclosures that are subject to harsh environments. The vent assembly provided by embodiments of the present technology is relatively small, has a low-profile, and is simple to manufacture and assemble. In configurations, it does not require an elastomeric part, adhesives, or complicated fastening methods to seal a water impervious member to the housing. Instead, the vent assembly of the present technology may include a water impervious but gas permeable membrane placed over vent holes formed in a wall of the enclosure and a vent cover and fastener that attach the membrane over the vent holes to allow air to pass through the membrane and the vent holes without elastomeric parts, adhesives, or complicated fastening methods. The vent cover also allows the membrane to be quickly and easily removed and replaced.

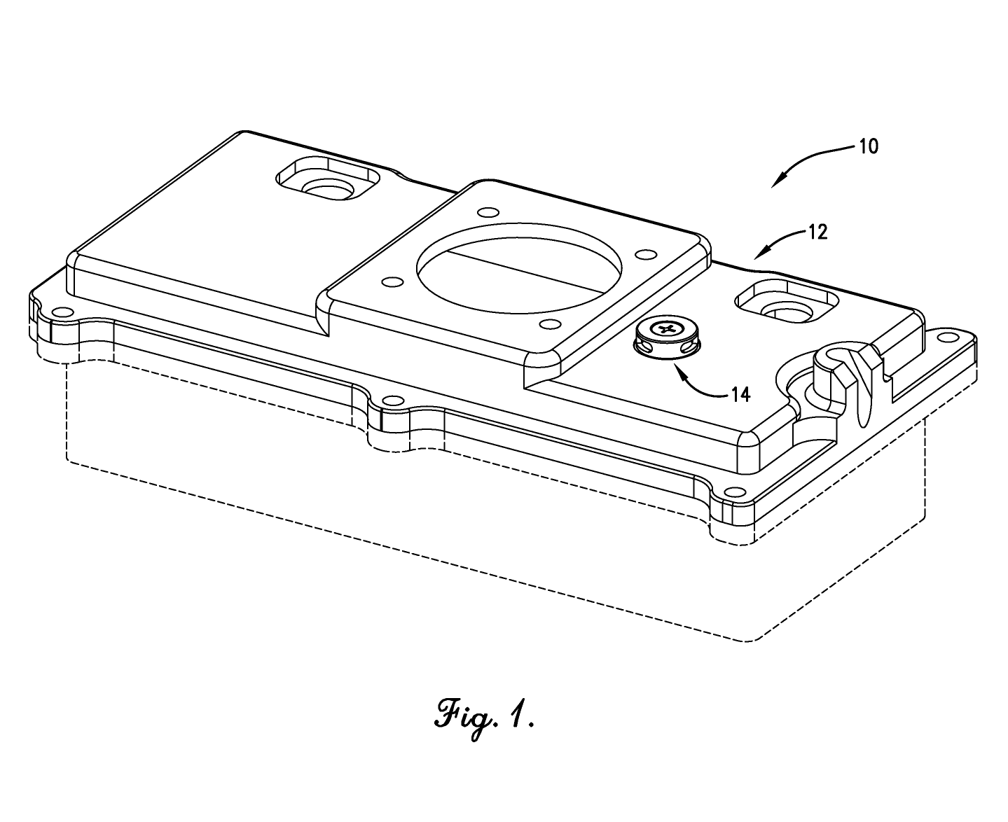

Exemplary embodiments of the present technology will now be described in more detail in connection with the attached drawing figures. One embodiment of the present technology is a housing 10 for an electronic device such as an avionics unit (e.g., panel-mount avionics devices such as navigation/communication systems, communication radios, flight displays, transponders, and the like), marine electronics such as chartplotters, portable and handheld electronic devices, etc. As best shown in FIG. 1, the housing 10 broadly includes a weatherproof enclosure 12 for enclosing the electronic device and one or more vent assemblies 14 integrated in the enclosure.

The enclosure 12 is conventional and may be formed in any size and shape and of any suitable materials such as aluminum, steel, or plastic. The enclosure 12 may include conventional gaskets, seals, connector openings, etc. In one embodiment, the enclosure 12 is sized and configured to house an aircraft transponder such as a Garmin GTX transponder.

The vent assemblies 14 are integrated into a wall, end plate, cover, or other portion of the enclosure 12 and are provided for venting the enclosure to equalize pressures and prevent condensation from forming on the enclosed electronics. Any number of vent assemblies 14 may be integrated in the enclosure 12, although the enclosure may only include one vent assembly 14.

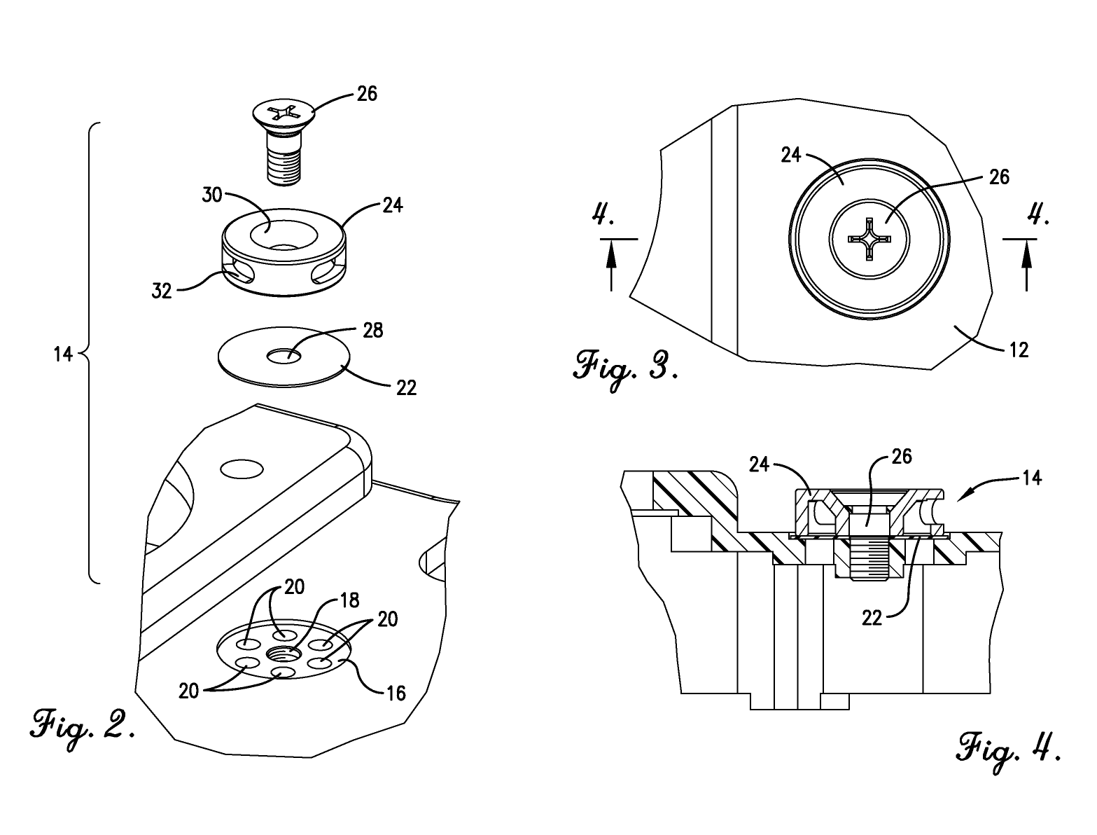

An embodiment of the vent assembly 14 is shown in FIG. 2 and comprises a recess 16 formed in the enclosure 12; a tapped hole 18 formed in the recess 16; one or more vent holes 20 positioned in the recess 16 and formed through the wall of the enclosure; a porous membrane 22 operable to be seated within the recess 16 and positioned over the vent holes 20; a vent cover 24 operable to be positioned at least partially over the porous membrane 22; and a fastener 26 for fastening the vent cover 24 to the enclosure.

In some embodiments, the recess 16, tapped hole 18, and vent holes 20 are formed in the enclosure 12 when it is fabricated. In other embodiments, the tapped hole 18 and vent holes 20 may be drilled or otherwise formed in the enclosure 12 after it has been fabricated and before it is placed in service.

The recess 16 is provided for receiving and seating the porous membrane 22 and may be formed anywhere on the enclosure 12 that does not interfere with other features of the enclosure. One embodiment of the recess 16 is formed on an end plate of the enclosure 12, is circular, and approximately 2″ in diameter and 0.02″ in depth. However, the recess 16 may be formed in any shape and size without departing from the scope of the present technology. Moreover, some embodiments of the vent assembly 14 may eliminate the recess 16 entirely.

The tapped hole 18 is provided for receiving the fastener 26 as described below and may be formed anywhere in the recess 16 or elsewhere on the enclosure if no recess 16 is formed in the enclosure. In one embodiment, the tapped hole 18 is approximately 0.09″ in diameter, positioned in the center of the recess 16. Some embodiments of the vent assembly 14 may use more than one tapped hole 18 and fastener 26. The tapped hole 18 may be through hole or blind hole.

The vent holes 20 are provided to allow air in and out of the enclosure and may be formed anywhere in the recess 16 or elsewhere on the enclosure 12 if no recess is provided. In one embodiment, six vent holes 20, each having a diameter of approximately 0.09″, are circumferentially spaced 60 degrees apart around the tapped hole 18. However, any number and size of vent holes 20 may be provided without departing from the scope of the present technology. For example, fewer but larger vent holes 20 may be provided or more but smaller vent holes 20 may be provided. The vent holes 20 may also be arranged in any pattern and positioned anywhere within the recess 16 or elsewhere on the enclosure.

The porous membrane 22 is seated within the recess 16 or placed directly over the vent holes 20 if no recess is provided. The porous membrane 22 prevents water or other liquids from passing through the vent holes 20 while permitting air or other gases to pass through the vent holes. The porous membrane 22 may be formed of a tear resistant, hydrophobic, and aleophobic or oleophobic material that is liquid impervious but gas permeable. In one embodiment, the porous membrane 22 is washer-shaped and has a central hole 28 through which the fastener 26 is inserted. An embodiment of the membrane may have an outer diameter of approximately 0.49″, a central hole diameter of approximately 0.125″, and a thickness of approximately 0.009″

Exemplary porous membranes that may be used in the vent assembly 14 include PALL VERSAPOR® acrylic copolymer membranes and/or POREX porous PTFE membranes. PALL VERSAPOR® acrylic copolymer membranes cast on a nonwoven nylon support have shown durability for use with enclosures in harsh environments. These are just several examples of porous membranes, and the vent assembly 14 may incorporate any porous membrane 22 without departing from the scope of the claims.

The vent cover 24 at least partially covers the porous membrane 22 so as to retain it in the recess 16 and over the vent holes 20. An embodiment of the vent cover 24 is cylindrical in shape, formed of aluminum, steel, or other suitable materials, and has a circular sidewall, a top surface, and a bottom surface. A hollow central passageway 30 may extend though the top and bottom surfaces for passage of the shank of the fastener 26. In one embodiment, the hollow central passageway 30 is countersunk so as to allow the head of the fastener 26 to be substantially flush with the top surface of the vent cover 24. At least one air passageway 32 may be formed in the vent cover 24 and is in pneumatic communication with the vent holes 20 so that air or other gases may pass between the enclosure 12, the vent holes 20, and the air passageway 32. One embodiment of the vent cover 24 includes three oblong air passageways 32 formed through the curved sidewall of the vent cover 24. Each air passageway 32 opens to the side of the circular sidewall and turns to open along the bottom surface of the vent cover 24. In one embodiment, each air passageway 32 is approximately 0.230″ long and 0.079″ tall.

The size, geometry, and number of air passageways 32 in the vent cover 24 determine what is allowed inside the vent cover 24 and what may be trapped inside the vent cover against the membrane 22. One embodiment of the vent cover 24 includes three large passageways 32 as described above to provide ample space for water and other contaminates to flow out of the vent cover since air flow can pull water and other contaminates into the vent cover. Such water or other contaminates could restrict air flow through the membrane 22 if allowed to collect inside the vent cover.

The fastener 26 secures the vent cover 24 to the enclosure 12 and allows it to be easily removed as described below. The fastener 26 additionally seals the vent cover 24 to the recess 16 (and/or enclosure 12 generally) as described below. In one embodiment, the fastener 26 is a self-sealing aluminum or metal screw that is inserted through the screw-receiving aperture 30 of the vent cover 24, though the central hole 28 in the porous membrane 22, and into the tapped hole 18. In configurations where the tapped hole 18 is a blind hole, the fastener 26 need not be a self-sealing screw.

When installed on the enclosure 12 as shown in FIG. 4, the vent assembly 14 permits air and other gases to vent in and out of the enclosure 12 through the vent holes 20 and the air passageway(s) 32. In configurations, the vent cover 24 creates a seal between the vent cover 24 and the recess 16 (and/or enclosure 12) so that the only path of air movement out of the enclosure 12 is through the vent holes 20, the membrane 22, and then the air passageway(s) 32. The porous membrane 22, which covers the vent holes 20, allows air and gases to pass through it but prevents water and other liquids from migrating into the enclosure 12. Because the vent cover 24 is secured to the enclosure with a self-sealing screw or other fastener, it can be easily removed so that the porous membrane 22 can be replaced often prolonged use and/or when it is desired to use a different porous membrane.

Such functionality enables different porous membranes to be used for different applications of the housing 10. When the housing 10 is used in applications where liquids are unlikely to come into contact with the vent assembly 14, a membrane 22 formed of a material that is highly porous and less impermeable to liquids may be used. Conversely, when the housing is used in applications where water and liquids frequently contact the vent assembly 14, a membrane 22 that is formed of a material that is less porous and highly impermeable to liquids may be used instead. Specific examples include the VERSAPOR® 5000R membrane which has a large air flow rate with water intrusion pressure greater than 2.0 psi, which makes it well suited for enclosures used in aviation applications. Enclosures that require greater water intrusion pressure due to possible water immersion or high pressure water streams may benefit from a VERSAPOR® 1200R membrane, which is highly resistant to water penetration.

Another advantage of providing a removable porous membrane 22 is that it may be removed and replaced with a new one if it becomes clogged, dirty, or damaged. Or, a membrane 22 that works well in one application as described above may be replaced with a different type of membrane if the enclosure is later used in a different application.

Although the present technology has been described with reference to the preferred embodiments illustrated in the attached drawing figures, it is noted that equivalents may be employed and substitutions made herein without departing from the scope of the technology as recited in the claims. For example, the sizes and shapes of the enclosure and vent assembly as described and illustrated herein may be changed without departing from the scope of the present technology.

Having thus described the preferred embodiment of the invention, what is claimed as new and desired to be protected by Letters Patent includes the following:

1. A vent assembly for venting an electronic device enclosure, the vent assembly comprising:
a porous membrane configured for placement over vent holes in the enclosure;
a vent cover configured for placement over the porous membrane so as to sandwich the porous membrane between the vent holes and the vent cover, the vent cover having at least one air passageway for directing air to and from the vent holes; and
a fastener for fastening the vent cover to the enclosure.

2. The vent assembly as set forth in claim 1, wherein the vent cover has a central aperture through which the fastener extends.

3. The vent assembly as set forth in claim 2, wherein the fastener is a screw that is inserted through the central aperture of the vent cover and into the tapped hole for fastening the vent cover to the housing.

4. The vent assembly as set forth in claim 1, wherein the porous membrane is formed of a material that is impervious to liquids but permeable to gases.

5. A vent assembly for venting air in and out of an electronic device enclosure, the vent assembly comprising:
a circular recess formed in a wall of the enclosure;
a tapped hole formed in a center of the circular recess and through the wall of the enclosure;
a number of vent holes positioned in the circular recess and formed through the wall of the enclosure, the vent holes being circumferentially spaced-apart around the tapped hole;
a circular porous membrane seated within the circular recess and positioned over the vent holes;
a vent cover positioned at least partially over the porous membrane so as to sandwich the porous membrane between the vent holes and the vent cover, the vent cover having a central screw-receiving aperture and at least one air passageway in pneumatic communication with the vent holes; and
a fastener for insertion through the screw-receiving aperture of the vent cover and into the tapped hole for fastening the vent cover to the enclosure.

6. The vent assembly as set forth in claim 5, wherein the fastener is a self-sealing screw.

7. The vent assembly as set forth in claim 5, wherein the vent assembly includes six vent holes.

8. The vent assembly as set forth in claim 5, wherein the vent cover includes at least two air passageways.

9. The vent assembly as set forth in claim 5, wherein the circular porous membrane is formed of a material that is impervious to liquids but permeable to gases.

10. The vent assembly as set forth in claim 5, wherein the circular porous membrane has a central hole for passage of the fastener.

11. A housing for an electronic device, the housing comprising:
an enclosure for at least partially enclosing the electronic device; and
a vent assembly for venting air in and out of the enclosure, the vent assembly comprising—
a number of vent holes formed through a wall of the enclosure;
a porous membrane positioned over the vent holes;
a vent cover positioned at least partially over the porous membrane so as to sandwich the porous membrane between the vent holes and the vent cover, the vent cover having at least one air passageway in pneumatic communication with the vent holes; and
a fastener for fastening the vent cover to the enclosure.

12. The housing as set forth in claim 11, the vent assembly further comprising a tapped hole formed through the wall of the enclosure, wherein the vent holes encircle the tapped hole.

13. The housing as set forth in claim 12, wherein the vent cover has a central screw-receiving aperture.

14. The housing as set forth in claim 13, wherein the fastener is a screw that is inserted through the central screw-receiving aperture of the vent cover and into the tapped hole for fastening the vent cover to the enclosure.

15. The housing as set forth in claim 11, the vent assembly further comprising a circular recess formed in the wall of the enclosure for receiving and seating the porous membrane.

16. The housing as set forth in claim 11, wherein the vent assembly comprises six vent holes that are circumferentially spaced-apart in a circle around the central tapped hole.

17. The housing as set forth in claim 11, wherein the porous membrane is formed of a material that is impervious to liquids but permeable to gases.
